(19) United States
(12) Patent Application Publication
(10) Pub. No.: US 2025/0107242 A1
(43) Pub. Date: Mar. 27, 2025

(54) SEMICONDUCTOR STRUCTURE AND METHOD FOR FORMING THE SAME

(71) Applicant: Invention and Collaboration Laboratory, Inc., Taipei City (TW)

(72) Inventors: Chao-Chun LU, Hsinchu (TW); Li-Ping HUANG, Hsinchu (TW)

(73) Assignee: Invention and Collaboration Laboratory, Inc., Taipei City (TW)

(21) Appl. No.: 18/894,408

(22) Filed: Sep. 24, 2024

Related U.S. Application Data
(60) Provisional application No. 63/540,112, filed on Sep. 25, 2023.

(51) Int. Cl. H01L 27/12; H01L 21/762; H01L 21/8238; H01L 27/092; H01L 29/66; H01L 29/78

(52) U.S. Cl. CPC H10D 87/00; H01L 21/762; H10D 30/0227; H10D 30/601; H10D 84/017; H10D 84/038; H10D 84/85

(57) ABSTRACT

A semiconductor structure includes a semiconductor substrate, an epitaxy layer, a dielectric layer, a semiconductor layer, a first semiconductor device and a second semiconductor device. The semiconductor substrate has first region and a second region. The epitaxy layer is disposed on and within the first region of the semiconductor substrate. The dielectric layer is disposed on and within the second region of the semiconductor substrate. The semiconductor layer is disposed on the dielectric layer and within the second region. The first semiconductor device is formed on the epitaxy layer. The second semiconductor device is formed on the semiconductor layer.

This application claims the benefit of U.S. application Ser. No. 63/540,112, filed Sep. 25, 2023, the subject matter of which is incorporated herein by reference.

### BACKGROUND

### Technical Field

The disclosure relates in generally to a semiconductor structure and method for fabricating the same, and in particular to a semiconductor structure with a selective localized silicon-on-insulator (SOI) device and method for fabricating the same.

### Description of the Related Art

Traditional bulk devices need to have a larger latch up design to avoid forming parasitic bipolar device and reduce current leakage. To take a complementary metal-oxide-semiconductor (CMOS) configuration including a PMOS transistor and an NMOS transistor formed in a bulk semiconductor substrate (such as, a bulk silicon substrate) as an example, a larger latch up design rule is required for forming an N+ to P+ spacing between the PMOS transistor and the NMOS transistor. Such that, it is hard to shrink the size of integrated circuits applying the conventional bulk devices.

SOI devices, for example a CMOS configuration made in an entire SOI wafer, have several advantages to create integrated circuits: (1) Each transistor is fully isolated from the other transistor; (2) The parasitic capacitances associated with source and drain regions of an MOSFET are significantly reduced; (3) there is no latch-up concern between the NMOS and PMOS transistors, which thus significantly reduces the planar area in contrast to that of a Bulk-substrate CMOS technology; (4) As a FinFET or Tri-Gate technology is used in a fully-depleted SOI device, there is no substrate leakage concern.

However, one disadvantage of the SOI device technology is that the SOI devices are processed on a entire SOI wafer and cannot electrically connected to the semiconductor layer underneath the silicon oxide layer if there was no extra interlayer connection is formed, which may be lacking of flexibility and limit the application of the SOI device. Such that, how to eliminate the major disadvantage of the SOI devices, but keep all advantages of using bulk device technology for forming a high performance circuit, has become one of the important topics in this technical field.

Therefore, there is a need of providing an improved semiconductor structure with a semiconductor island and method for fabricating the same to obviate the drawbacks encountered from the prior art.

### SUMMARY

One aspect of the present disclosure is to provide a semiconductor structure, wherein the semiconductor structure includes a semiconductor substrate, an epitaxy layer, a dielectric layer, a semiconductor layer, a first semiconductor device and a second semiconductor device. The semiconductor substrate has first region and a second region. The epitaxy layer is disposed on and within the first region of the semiconductor substrate. The dielectric layer is disposed on and within the second surface of the semiconductor substrate. The semiconductor layer is disposed on the dielectric layer. The first semiconductor device is formed on the epitaxy layer. The second semiconductor device is formed on the semiconductor layer.

In one embodiment of the present disclosure, the epitaxy layer is extended upward from a portion surface of the semiconductor substrate in the first region.

In one embodiment of the present disclosure, the dielectric layer is an oxide layer, the oxide layer contacts with another portion surface of the semiconductor substrate in the second region.

In one embodiment of the present disclosure, the semiconductor layer is a silicon layer; a top surface of the silicon layer is substantially conformal with a top surface of the epitaxy layer.

In one embodiment of the present disclosure, the first semiconductor device is a metal-oxide-semiconductor-field-effect-transistor (MOSFET) transistor includes a first source/drain disposed within the epitaxy layer and a first localized isolation below the first source/drain.

In one embodiment of the present disclosure, the first localized isolation includes a first horizontally extended isolation portion insulating a bottom surface of the first source/drain from the semiconductor substrate, and a first vertically extended isolation portion at least partially insulating a sidewall of the first source/drain from the semiconductor substrate.

In one embodiment of the present disclosure, the semiconductor layer is a silicon layer; the second semiconductor device is another MOSFET includes a second source/drain disposed within the silicon layer; the second semiconductor device further includes a second localized isolation disposed below the second source/drain, the second localized isolation includes a second horizontally extended isolation portion insulating a bottom surface of the second source/drain from the silicon layer, and a second vertically extended isolation portion at least partially insulating a sidewall of the second source/drain from the silicon layer.

In one embodiment of the present disclosure, the dielectric layer is an oxide layer; a bottom of the epitaxial layer is aligned or substantially aligned with a bottom of the oxide layer.

In one embodiment of the present disclosure, the semiconductor layer is a silicon layer, a vertical thickness of the epitaxial layer is larger than that of the silicon layer.

In one embodiment of the present disclosure, the combination of the semiconductor substrate, the dielectric layer and the semiconductor layer is a selective localized SOI substrate.

Yet another aspect of the present disclosure is to provide a method to form a semiconductor structure, wherein the method for forming a semiconductor structure includes steps as follows: Firstly, a SOI substrate including a semiconductor substrate, an oxide layer and a silicon layer stacked in sequence is provided. A dielectric layer is then formed on the silicon layer. Next, portions of the dielectric layer, the silicon layer and the oxide layer are removed to expose a first region of the semiconductor substrate and remain portions of the dielectric layer, the silicon layer and the oxide layer within a second region of the semiconductor substrate. An epitaxy layer is then formed on the first region. Subsequently, a first semiconductor device is formed on the epitaxy layer; and a second semiconductor device is formed on the remaining portion of the silicon layer respectively.

In one embodiment of the present disclosure, the forming of the epitaxy layer includes steps of performing a selective epitaxial growth (SEG) process to grow epitaxial material from the exposed first region; removing the remaining portion of the dielectric layer disposed on the second region; and palanarizing the epitaxial material to form the epitaxy layer; and removing the remaining portion of the dielectric layer disposed within the second region.

In one embodiment of the present disclosure, the epitaxial material is palanarized by using the remaining portion of the dielectric layer disposed on the second region as a stop layer to make the epitaxy layer having a top surface substantially conformal to a top surface of the silicon layer.

In one embodiment of the present disclosure, the process for forming the first semiconductor device includes steps as follows: Firstly, a first gate structure is formed on the top surface of the epitaxy layer. Next, a first trench is formed below the top surface of the epitaxy layer and adjacent to the first gate structure. Then, a first localized isolation is formed in the first trench. Subsequently, a first source/drain is formed in the first trench.

In one embodiment of the present disclosure, the forming of the first localized isolation includes steps of performing a thermal oxidation process to form a first horizontally extended isolation portion on a bottom surface of the first trench and a first vertically extended isolation portion on sidewalls of the first trench; and removing a portion of the first vertically extended isolation portion to expose a portion of the epitaxy layer under the first gate structure.

In one embodiment of the present disclosure, the forming of the first source/drain includes steps of performing a selective growth process to form a first lightly doped-drain (LDD) region from the exposed portion of the epitaxy layer under the first gate structure; and forming a first conductive region in the first trench to electrically connected to the first LDD region.

In one embodiment of the present disclosure, the forming of the second semiconductor device includes steps as follows: Firstly, a second gate structure is formed on the original surface of the semiconductor substrate. Next, a second trench is formed below the original surface of the semiconductor substrate and adjacent to the second gate structure. A second source/drain is then formed in the second trench.

In one embodiment of the present disclosure, prior to forming the second source/drain, the method further includes steps of forming a second localized isolation in the second trench.

In one embodiment of the present disclosure, the forming of the first localized isolation includes steps of performing a thermal oxidation process to form a second horizontally extended isolation portion on a bottom surface of the second trench and a second vertically extended isolation portion on sidewalls of the second trench; and removing a portion of the second vertically extended isolation portion to expose a portion of the silicon layer under the second gate structure.

In accordance with the aforementioned embodiments of the present disclosure, a semiconductor structure both having a bulk semiconductor substrate and a selective localized SOI substrate is provided based on a SOI substrate. Such that, it can effectively reduce the size of latch up design and provide devices flexibility at the same time.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1A is a top view illustrating the structure after a SOI substrate is provided according to one embodiment of the present disclosure;

FIG. 1B is a cross-sectional view taken along the cutting line C1 as depicted in FIG. 1A;

FIG. 2A is a top view illustrating the structure after the dielectric layer is formed according to one embodiment of the present disclosure;

FIG. 2B is a cross-sectional view taken along the cutting line C2 as depicted in FIG. 2A;

FIG. 3A is a top view illustrating the structure after the first region and the second region of the semiconductor substrate are defined according to one embodiment of the present disclosure;

FIG. 3B is a cross-sectional view taken along the cutting line C3 as depicted in FIG. 3A;

FIG. 4A is a top view illustrating the structure after the epitaxial material are grown in the first region according to one embodiment of the present disclosure;

FIG. 4B is a cross-sectional view taken along the cutting line C4 as depicted in FIG. 4A;

FIG. 5A is a top view illustrating the structure after the epitaxial material is palanarized according to one embodiment of the present disclosure;

FIG. 5B is a cross-sectional view taken along the cutting line C5 as depicted in FIG. 5A;

FIG. 6A is a cross-sectional view illustrating the structure after the first gate structure is formed on the top surface of the epitaxy layer according to one embodiment of the present disclosure;

FIG. 6B is a cross-sectional view illustrating the structure after the trenches are formed according to one embodiment of the present disclosure;

FIG. 6C is a cross-sectional view illustrating the structure after the localized isolations are formed according to one embodiment of the present disclosure;

FIG. 6D is a cross-sectional view illustrating the structure after the source and the drain are formed according to one embodiment of the present disclosure;

FIG. 7A is a cross-sectional view illustrating the structure after the second gate structure is formed on the silicon layer according to one embodiment of the present disclosure;

FIG. 7B is a cross-sectional view illustrating the structure after the trenches are formed according to one embodiment of the present disclosure;

FIG. 7C is a cross-sectional view illustrating the structure after the localized isolations are formed according to one embodiment of the present disclosure;

FIG. 7D is a cross-sectional view illustrating the structure after the source and the drain are formed according to one embodiment of the present disclosure; and

FIG. 8 is a cross-sectional view illustrating the semiconductor structure having a bulk semiconductor substrate and a selective localized SOI substrate according to one embodiment of the present disclosure.

FIG. 9 is a cross-sectional view illustrating the semiconductor structure having a bulk semiconductor substrate and a selective localized SOI substrate according to another embodiment of the present disclosure.

### DETAILED DESCRIPTION

The embodiments as illustrated below provide a semiconductor structure 10 having a bulk semiconductor substrate and a selective localized SOI substrate and method for fabricating the same, that can effectively reduce the size of latch up design and provide devices flexibility at the same time. The present disclosure will now be described more specifically with reference to the following embodiments illustrating the structure and arrangements thereof.

It is to be noted that the following descriptions of preferred embodiments of this disclosure are presented herein for purpose of illustration and description only. It is not intended to be exhaustive or to be limited to the precise form disclosed. Also, it is also important to point out that there may be other features, elements, steps and parameters for implementing the embodiments of the present disclosure which are not specifically illustrated. Thus, the specification and the drawings are to be regard as an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

The forming of the semiconductor structure 10 includes steps as follows:
Step S11: providing a SOI substrate 100 including a semiconductor substrate 101, an oxide layer 102 and a silicon or semiconductor layer 103 stacked in sequences;
Step S12: forming a dielectric layer 104 on the silicon layer 103;
Step S13: removing portions of the dielectric layer 104, the silicon layer 103 and the oxide layer 102 to expose a first region 101A of the semiconductor substrate 101 and remain portions of the dielectric layer 104, the silicon layer 103 and the oxide layer 102 on a second region 101B of the semiconductor substrate 101.
Step S14: forming an epitaxy layer 105 on the first region 101A.
   Sub-Step S141: performing a selective epitaxial growth (SEG) process to grow epitaxial material 105M from an exposed portion of an original surface 101s of the semiconductor substrate 101 in the first region 101A;
   Sub-Step S142: palanarizing the epitaxial material 105M to form the epitaxy layer 105; and
   Sub-Step S143: removing the remaining portion of the dielectric layer 104 disposed on the second region 101B.
Step S15: forming a first semiconductor device 110 on the epitaxy layer 105:
   Sub-Step S151: forming a first gate structure 106 on the top surface 105t of the epitaxy layer 105;
   Sub-Step S152: forming two trenches 107A and 107B below the top surface 105t of the epitaxy layer 105 and adjacent to the first gate structure 106;
   Sub-Step S153: forming localized isolations 108A and 108B respectively in the trenches 107A and 107B; and
   Sub-Step S154: forming a source 109A and a drain 109 respectively in the trenches 107A and 107B to correspondingly connect with the localized isolations 108A and 108B; and
Step S16: forming a second semiconductor device 120 on the remaining portion of the silicon layer 103:
   Sub-Step S161: forming a second gate structure 126 on the top surface 103t of the silicon layer 103;
   Sub-Step S162: forming two trenches 127A and 127B below the top surface 103t of the silicon layer 103 and adjacent to the second gate structure 126;
   Sub-Step S163: forming two localized isolations 128A and 128B respectively in the trenches 127A and 127B; and
   Sub-Step S164: forming a source 129A and a drain 129B in respectively the trenches 127A and 127B correspondingly connected to the localized isolations 128A and 128B.

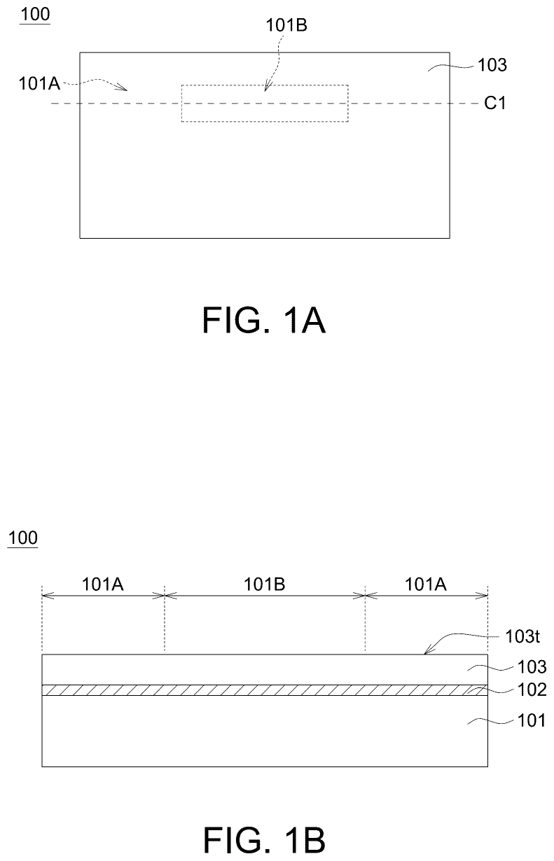

Refer to Step S11, a SOI substrate 100 including a semiconductor substrate 101, an extended oxide layer (or other dielectric layer) 102 and an extended silicon layer (or other semiconductor layer) 103 stacked in sequence is provided. In the present embodiment, the SOI substrate 100 is an entire SOI wafer, that is the oxide layer 102 is extended all over the surface of the semiconductor substrate 101. FIG. 1A is a top view illustrating the structure after a SOI substrate 100 is provided according to one embodiment of the present disclosure. FIG. 1B is a cross-sectional view taken along the cutting line C1 as depicted in FIG. 1A.

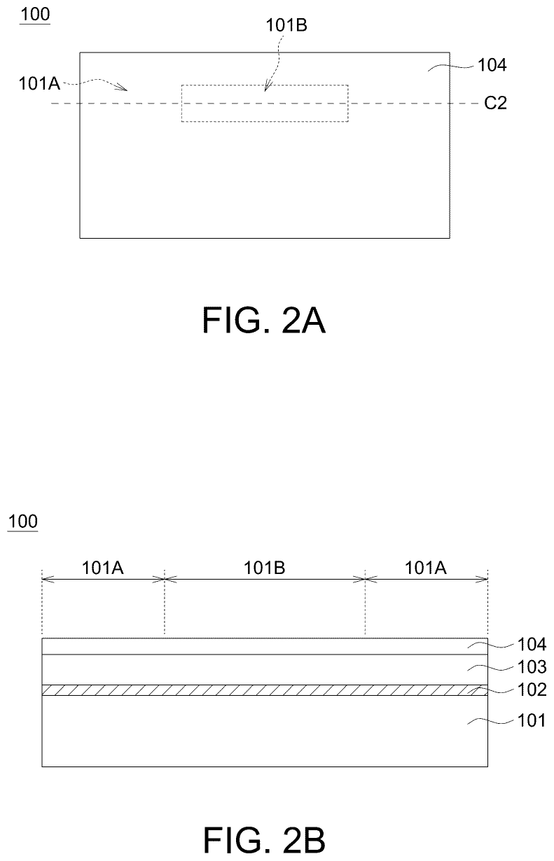

Refer to Step S12, a dielectric layer 104 is formed on the silicon layer 103. FIG. 2A is a top view illustrating the structure after the dielectric layer 104 is formed according to one embodiment of the present disclosure. FIG. 2B is a cross-sectional view taken along the cutting line C2 as depicted in FIG. 2A.

In some embodiments of the present disclosure, the dielectric layer 104 may be made of silicon oxide, silicon nitride, silicon carbide, silicon oxynitride, silicon oxycarbide or the arbitrary combinations thereof. In the present embodiment, the dielectric layer 104 may be a silicon dioxide layer formed by a deposition processes (e.g., low pressure chemical vapor deposition (LPCVD)) performed on the silicon layer 103 of the entire SOI wafer.

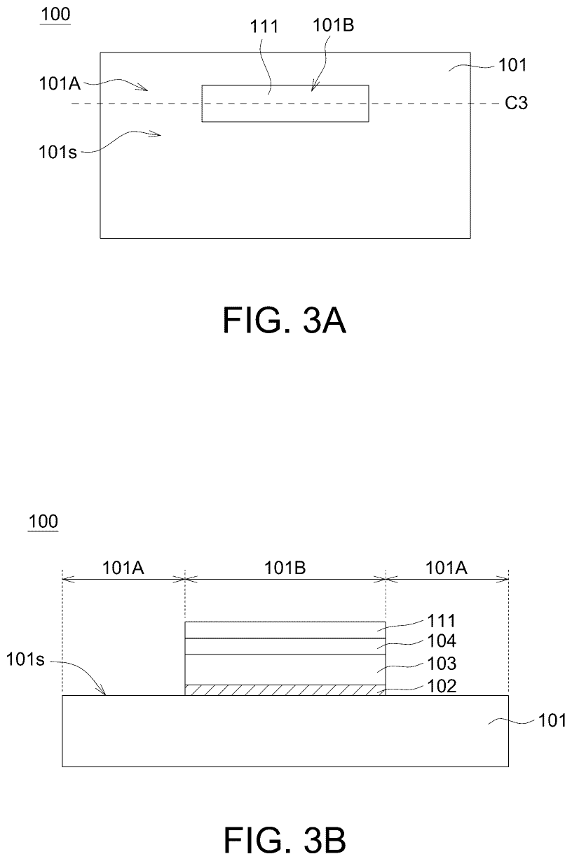

Refer to Step S13, portions of the dielectric layer 104, the silicon layer 103 and the oxide layer 102 are removed to form recess region and to expose a first region 101A of the semiconductor substrate 101 and remain portions of the dielectric layer 104, the silicon layer 103 and the oxide layer 102 on a second region 101B of the semiconductor substrate 101. FIG. 3A is a top view illustrating the structure after the first region 101A and the second region 101B of the semiconductor substrate 101 are defined according to one embodiment of the present disclosure. FIG. 3B is a cross-sectional view taken along the cutting line C3 as depicted in FIG. 3A.

In the present embodiment, an anisotropic etch (such as, a dry etching or a reactive ion etching (RIE)) process using a patterned photoresist layer 111 as an etching mask is performed to remove portions of the dielectric layer 104, the silicon layer 103 and the oxide layer 102, wherein the region of the semiconductor substrate 101 not covered by the patterned photoresist layer 111 can be referred to as the first region 101A and the region of the semiconductor substrate 101 covered by the patterned photoresist layer 111 can be referred to as the second region 101B. After the anisotropic etch process is carried out, a portion of an original surface 101s of the semiconductor substrate 101 in the first region 101A can be exposed; and the remaining portions of the dielectric layer 104, the silicon layer 103 and the oxide layer 102 can be disposed on the second region 101B.

Refer to Step S14, an epitaxy layer 105 is grown on the first region 101A. In some embodiments of the present disclosure, the forming of the epitaxy layer 105 includes Sub-steps S141 to S143 described below:

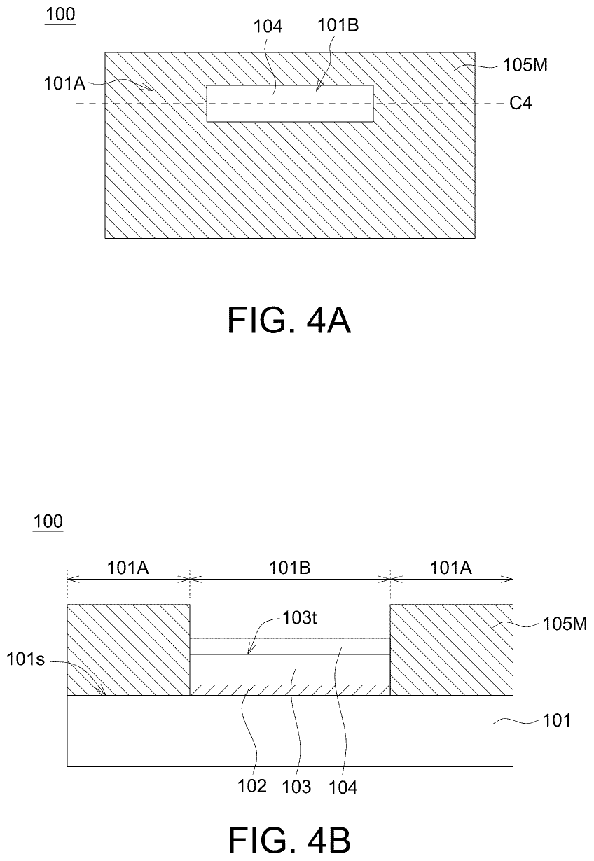

Refer to Sub-step S141, a SEG process is performed to grow epitaxial material 105M from the exposed portion of the original surface 101s of the semiconductor substrate 101 in the first region 101A. FIG. 4A is a top view illustrating the structure after the epitaxial material 105M are grown in the first region 101A according to one embodiment of the present disclosure. FIG. 4B is a cross-sectional view taken along the cutting line C4 as depicted in FIG. 4A.

In some embodiments of the present disclosure, the SEG process used to grow the epitaxial material 105M can be an atomic layer deposition (ALD) process, and the epitaxial material 105M includes silicon (Si), silicon germanium (SiGe), Gallium (Ga), gallium nitride (GaN), Gallium arsenide (GaAs), SiC or the arbitrary combination thereof.

In the present embodiment, the epitaxial material 105M is epitaxial silicon formed on the exposed portion of the original surface 101s of the semiconductor substrate 101 by an epitaxial growth process. Since the other portion of the original surface 101s of the semiconductor substrate 101 in the second region 101B are covered by the remaining portions of the silicon layer 103 and the dielectric layer 104, thus no any epitaxial silicon can be formed thereon.

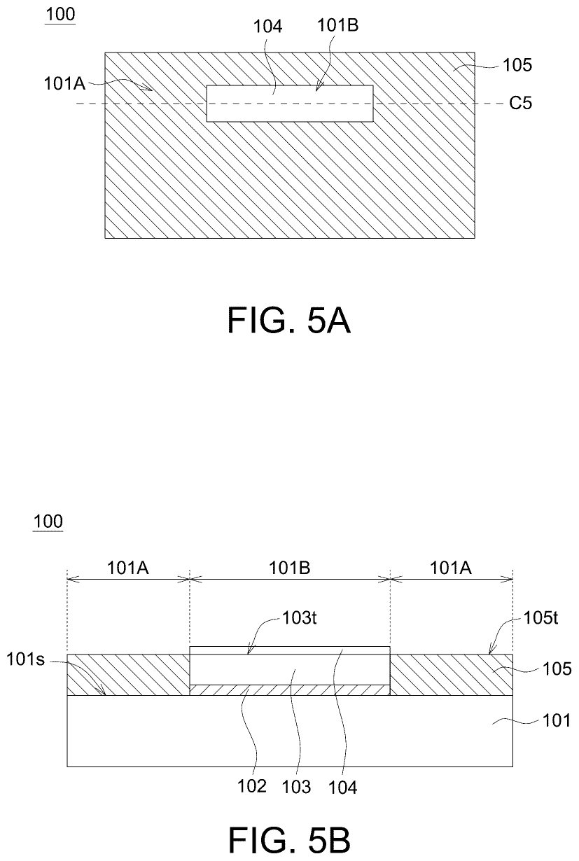

Refer to Sub-step S142, the epitaxial material 105M is palanarized to form the epitaxy layer 105. FIG. 5A is a top view illustrating the structure after the epitaxial material 105M is palanarized according to one embodiment of the present disclosure. FIG. 5B is a cross-sectional view taken along the cutting line C5 as depicted in FIG. 5A.

In some embodiments of the present disclosure, a planarization process, such as a chemical-mechanical planarization (CMP) process using the remaining portion of the dielectric layer 104 as a stop layer, is performed to remove a portion of the epitaxial material 105M, so as to form the epitaxy layer 105 having a top surface 105t substantially conformal to a top surface 103t of the silicon layer 103.

Refer to Sub-step S143, the remaining portion of the dielectric layer 104 disposed on the second region 101B could be removed in the event some semiconductor device will be made in this second region 101B. In some embodiments of the present disclosure, an isotropic etch process (such as, a buffer oxide etching (BOE) using an etchant including ammonium fluoride (NH4F) and hydrofluoric acid (HF)) is performed to remove the remaining portion of the dielectric layer 104 disposed on the second region 101B. Therefore, a partial SOI substrate is provided according to the present invention, wherein in one embodiment, the oxide layer or other dielectric material 102 only covers portion of the semiconductor substrate (or only within the second region 101B), and no oxide layer or other dielectric material 102 is under the epitaxial layer 105 (or no oxide layer or other dielectric material 102 is within the first region 101A). The bottom of the epitaxial layer 105 could be aligned or substantially aligned with the bottom of the oxide layer 102. The top of the epitaxial layer 105 could be aligned or substantially aligned with the top of the semiconductor layer 103. Thus, in one embodiment, the vertical thickness of the epitaxial layer 105 is larger than that of the epitaxial layer 105.

Refer to Step S15, a first semiconductor device 110 is formed on the epitaxy layer 105. In some embodiments of the present disclosure, the forming of the first semiconductor device 110 includes Sub-steps S151 to S154 described below:

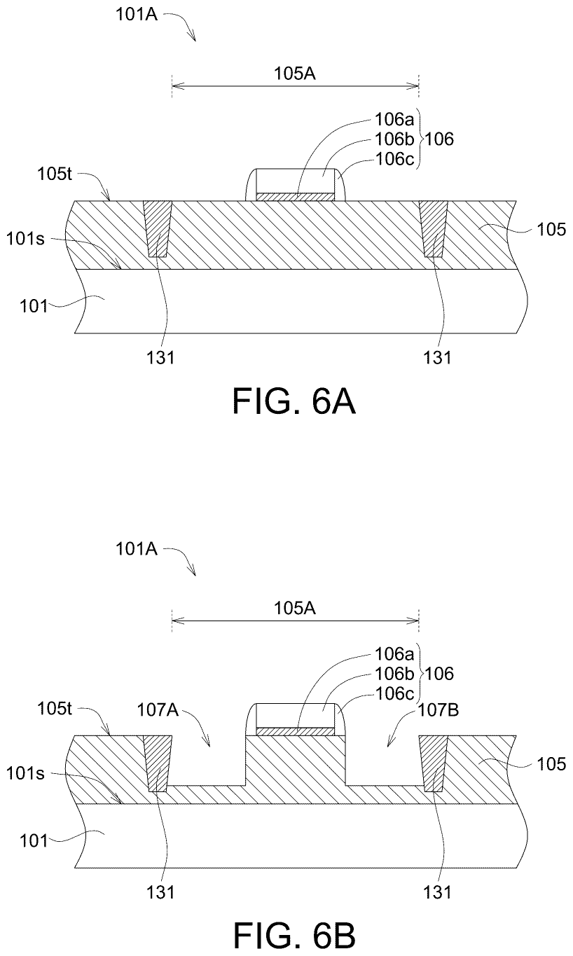

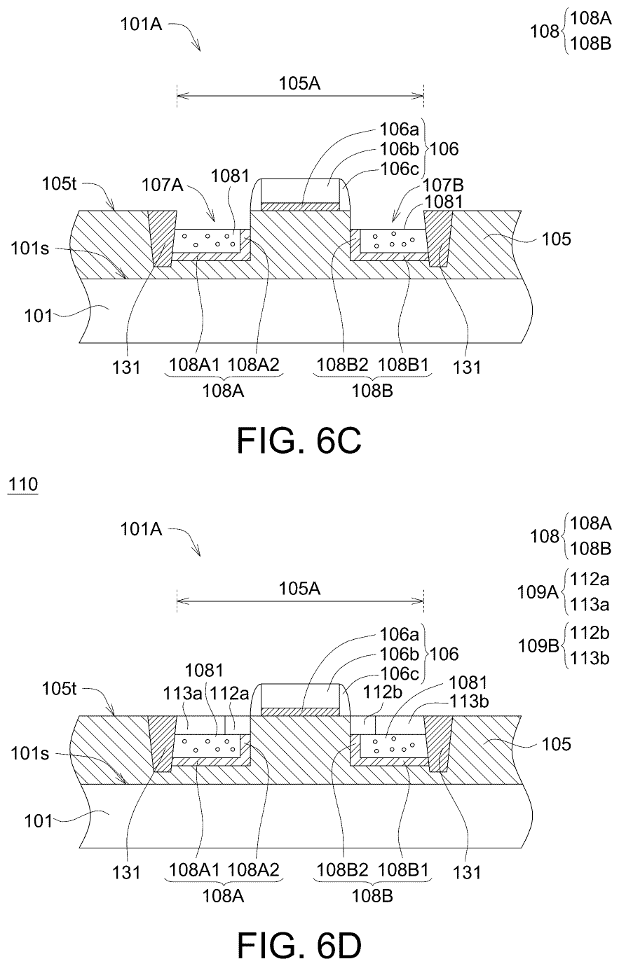

Refer to Sub-step S151, a first gate structure 106 is formed on the top surface 105t of the epitaxy layer 105. FIG. 6A is a cross-sectional view illustrating the structure after the first gate structure 106 is formed on the top surface 105t of the epitaxy layer 105 according to one embodiment of the present disclosure.

In some embodiments of the present disclosure, prior to forming the first gate structure 106, a shallow trench isolation (STI) 131 in the epitaxy layer 105 is formed to define an active region 105A on the first region 101A of the semiconductor substrate 101. In the present embodiment, a portion of the STI 131 extends downward in to the epitaxy layer 105 from the top surface 105t of the epitaxy layer 105; and another portion of the STI 131 may extend upward over the top surface 105t. In another embodiment, the portion of the STI 131 extends downward from the top surface 105t of the epitaxy layer 105 into the semiconductor substrate 101

The forming of the first gate structure 106 includes steps as follows: A gate dielectric layer 106a is firstly formed on the top surface 105t of the epitaxy layer 105 within the active region 105A. Next, a gate electrode 106b is then formed on the gate dielectric layer 106a. Spacers 106c are then formed on sidewalls of the stacked structure of the gate dielectric layer 106a and the gate electrode 106b. The combination of the gate dielectric layer 106a, the gate electrode 106b and the spacers 106c forms the first gate structure 106.

Refer to Sub-step S152, two trenches 107A and 107B are formed below the top surface 105t of the epitaxy layer 105 and adjacent to the first gate structure 106. FIG. 6B is a cross-sectional view illustrating the structure after the trenches 107A and 107B are formed according to one embodiment of the present disclosure.

In some embodiments of the present disclosure, the trenches 107A and 107B are formed by performing an anisotropic etch (such as, a dry etching or a RIE) process to remove a portion of the epitaxy layer 105 in the active region 105A.

Referring to sub-step S153: two localized isolations 108A and 108B are formed respectively in the trenches 107A and 107B. FIG. 6C is a cross-sectional view illustrating the structure after the localized isolations 108A and 108B are formed according to one embodiment of the present disclosure.

In some embodiments of the present disclosure, the forming of the localized isolations 108A and 108B includes steps as follows: Firstly, a thermal oxidation process is performed to form a thermal oxide layer 108 (such as, a silicon oxide layer) on the bottom and the sidewalls of the trenches 107A (or 107B). As shown in FIG. 6C, each portion of the thermal oxide layer 108 (referred to as the localized isolation 108A or 108B) formed in each of the trenches 107A and 107B has a horizontally extended isolation portion 108A1 (or 108B1) contacting with the bottom surface of the corresponding trench 107A (or 107B), and a vertically extended isolation portion 108A2 (or 108B2) contacting with the sidewalls of the corresponding trench 107A (or 107B). Next, a portion of the vertically extended isolation portion 108B may be removed to expose a portion of the epitaxy layer 105 under the first gate structure 106. Before removing the portion of the vertically extended isolation portion 108B, a nitride layer 1081 could be optionally deposited on the horizontally extended isolation portion 108A1 (or 108B1) as an etching reference and protect the non-etched portion of the localized isolation 108A or 108B.

Referring to sub-step S154: a source 109A and a drain 109B are respectively formed in the trenches 107A and 107B to correspondingly connect with the localized isolations 108A and 108B. FIG. 6D is a cross-sectional view illustrating the structure after the source 109A and the drain 109 are formed according to one embodiment of the present disclosure.

In some embodiments of the present disclosure, the forming of the source 109A and a drain 109B includes steps as follows: Firstly, a selective growth process (such as, an ALD process or a silicon epitaxial growth process) is performed to form lightly doped-drain (LDD) regions 112a and 112b from the exposed portion of epitaxy layer 105 under the first gate structure 106. Then conductive regions (or heavily doped regions) 113a and 113b are formed (such as by selective growth process) respectively in the trenches 107A and 107B to electrically connect to the LDD region 112A and 112B. In another embodiment (not shown), the heavily doped regions 113a and 113b do not touch the STI region 131 and there are gaps between the heavily doped regions 113a/113b and the STI region 131, respectively. Then a metal material is deposited the gap such that the metal is contacted a most lateral sidewall of the heavily doped region 113a (or 113b) and a top surface of the heavily doped regions 113a (or 113b). Such metal-semiconductor junction could reduce the contact resistance of the source/drain regions.

The combination of the LDD region 112a and the conductive region 113a forms the source 109A; and the combination of the LDD region 112b and the conductive region 113b forms the drain 109B. A MOSFET transistor (referred to as, the first semiconductor device 110) thus can be formed on/in the epitaxy layer 105. In the present embodiment the first semiconductor device 110 can be a P-type MOSFET transistor. The epitaxy layer 105 has N-type conductivity (also referred to as an N-type substrate or well), the source 109A and drain 109B have P-type conductivity. In the present embodiment the first semiconductor device 110 can be a N-type MOSFET transistor. The epitaxy layer 105 has P-type conductivity (also referred to as an P-type substrate or well), the source 109A and drain 109B have N-type conductivity.

Refer to Step S16, a second semiconductor device 120 could be formed on the silicon layer 103. In some embodiments of the present disclosure, the forming of the second semiconductor device 120 includes Sub-steps S161 to S164 described below:

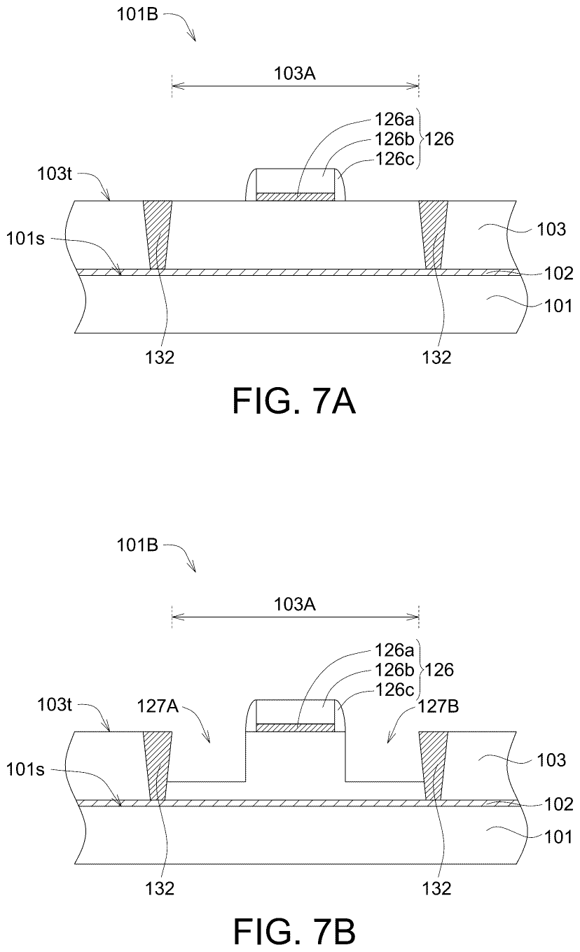

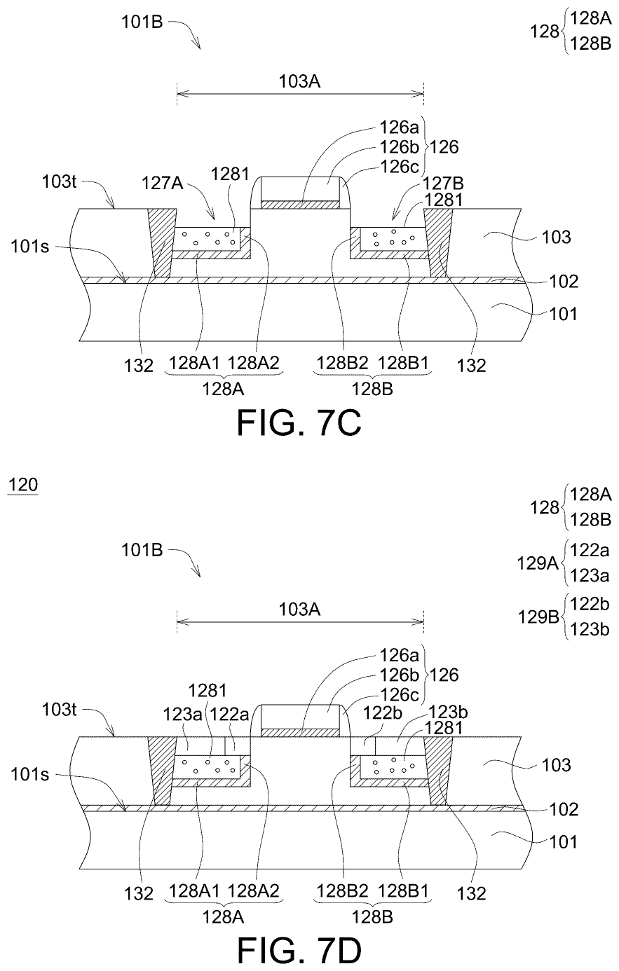

Refer to Sub-step S16, a second gate structure 126 is formed on the top surface 103t of the silicon layer 103. FIG. 7A is a cross-sectional view illustrating the structure after the second gate structure 126 is formed on the silicon layer 103 according to one embodiment of the present disclosure. In some embodiments of the present disclosure, prior to forming the second gate structure 126, a STI 132 in the silicon layer 103 is formed to define an active region 103A on the second region 101B of the semiconductor substrate 101. In the present embodiment, a portion of the STI 132 extends downward in to the silicon layer 103 from the top surface 103t of the silicon layer 103 (but not touch the oxide layer 102); and another portion of the STI 132 may extend upward over the top surface 103t. In another embodiment, the portion of the STI 132 extends downward from the top surface 105t of the epitaxy layer 105 to the oxide layer 102 (as shown in FIG. 7B) or to the semiconductor substrate 101.

The forming of the second gate structure 126 includes steps as follows: A gate dielectric layer 126a is firstly formed on the top surface 103t of the silicon layer 103 within the active region 103A. Next, a gate electrode 126b is then formed on the gate dielectric layer 126a. Spacers 126c are then formed on sidewalls of the stacked structure of the gate dielectric layer 126a and the gate electrode 126b. The combination of the gate dielectric layer 126a, the gate electrode 126b and the spacers 126c forms the second gate structure 126.

Refer to Sub-step S162, two trenches 127A and 127B are formed below the top surface 135t of the silicon layer 103 and adjacent to the second gate structure 126. FIG. 7B is a cross-sectional view illustrating the structure after the trenches 127A and 127B are formed according to one embodiment of the present disclosure.

In some embodiments of the present disclosure, the trenches 127A and 127B are formed by performing an anisotropic etch (such as, a dry etching or a RIE) process to remove a portion of the silicon layer 103 in the active region 103A.

Referring to sub-step S163: two localized isolations 128A and 128B are formed respectively in the trenches 127A and 127B. FIG. 7C is a cross-sectional view illustrating the structure after the localized isolations 128A and 128B are formed according to one embodiment of the present disclosure.

In some embodiments of the present disclosure, the forming of the localized isolations 128A and 128B includes steps as follows: Firstly, a thermal oxidation process is performed to form a thermal oxide layer 128 (such as, a silicon oxide layer) on the bottom and the sidewalls of the trenches 127A and 127B. As shown in FIG. 7C, each portion of the thermal oxide layer 128 (referred to as the localized isolation 128A or 128B) formed in each of the trenches 127A and 127B has a horizontally extended isolation portion 128A (or 128B) contacting with the bottom surface of the corresponding trench 127A1 (or 127B1), and a vertically extended isolation portion 128A2 (or 128B2) contacting with the sidewalls of the corresponding trench 127A (or 127B). Next, a portion of the vertically extended isolation portion 128A2 (or 128B2) may be removed to expose a portion of the silicon layer 103 under the first gate structure 126. Before removing the portion of the vertically extended isolation portion 128B, a nitride layer 1281 could be optionally deposited on the horizontally extended isolation portion 128A1 (or 128B1) as an etching reference and protect the non-etched portion of the localized isolation 128A or 128B.

Referring to sub-step S164: a source 129A and a drain 129 are respectively formed in the trenches 127A and 127B to correspondingly connect with the localized isolations 128A and 128B. FIG. 7D is a cross-sectional view illustrating the structure after the source 129A and the drain 129B are formed according to one embodiment of the present disclosure.

In some embodiments of the present disclosure, the forming of the source 109A and a drain 109 includes steps as follows: Firstly, a selective growth process (such as, an ALD process or a silicon epitaxial growth process) is performed to form LDD regions 122a and 122b from the exposed portion of epitaxy layer 105 under the first gate structure 106. Then conductive regions (or heavily doped regions) 123a and 123b are formed (such as by selective growth process) respectively in the trenches 127A and 127B to electrically connected to the LDD region 122A and 122B. In another embodiment (not shown), the heavily doped regions 123a and 123b do not touch the STI region 132 and there are gaps between the heavily doped regions 123a/123b and the STI region 132, respectively. Then a metal material is deposited the gap such that the metal is contacted a most lateral sidewall of the heavily doped region 123a (or 123b) and a top surface of the heavily doped regions 123a (or 123b). Such metal-semiconductor junction could reduce the contact resistance of the source/drain regions.

The combination of the LDD region 122a and the conductive region 123a forms the source 129A; and the combination of the LDD region 122b and the conductive region 123b forms the drain 129B. A MOSFET transistor (referred to as, the second semiconductor device 120) thus can be formed on/in the silicon layer 103.

In the present embodiment the second semiconductor device 120 can be an N-type MOSFET transistor. The silicon layer 103 has P-type conductivity (also referred to as a P-type substrate), the source 129A and drain 129B have N-type conductivity. In the present embodiment the second semiconductor device 120 can be an P-type MOSFET transistor. The silicon layer 103 has N-type conductivity (also referred to as a P-type substrate or well), the source 129A and drain 129B have P-type conductivity.

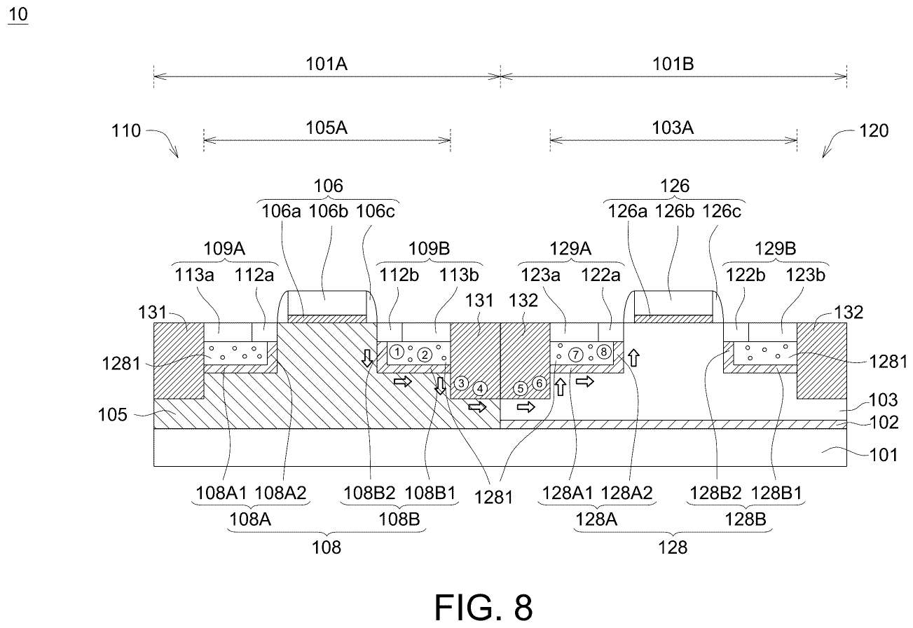

Subsequently, a series of downstream processes, such as a metal damascene process, are performed to form at least one contact structure (not shown), so as to complete the preparation of the semiconductor structure 10 having a bulk semiconductor substrate (the combination of the semiconductor substrate 101 and the epitaxy layer 105) and a selective localized SOI substrate (the semiconductor substrate 101, the dielectric layer 104 and the silicon layer 103) as shown in FIG. 8.

As shown in FIG. 8, since the first semiconductor device 110 (P-type MOSFET) and the second semiconductor device 120 (N-type MOSFET) are located respectively inside some adjacent regions, and the silicon layer 103 (P-type substrate) and the epitaxy layer 105 (N-type substrate) are formed next to each other within a close neighborhood, thus a parasitic junction structure called n+/p/n/p+ parasitic bipolar device can be formed with its contour starting from the n+region (he source 129A) of the second semiconductor device 120 (N-type MOSFET) to the silicon layer 103 (P-type substrate) to the neighboring the epitaxy layer 105 (N-type substrate) and further up to the p+region (the source 109A) of the first semiconductor device 110 (P-type MOSFET).

On one hand, if the first semiconductor device 110 and the second semiconductor device 120 did not have the localized isolations 108A, 108B, 128A and 128B, there may be significant noises occurred on either n+/p junctions or p+/n junctions, an extraordinarily large current may flow through this n+/p/n/p+ junction abnormally which can possibly shut down some operations of the CMOS circuit (including the first semiconductor device 110 and the second semiconductor device 120) to cause malfunction thereof. Such an abnormal phenomenon called Latch-up is detrimental for CMOS operations and must be avoided.

On the other hand, the configuration of the localized isolations 108A, 108B, 128A and 128B can result in a much longer path from the n+/p junction through the p-substrate/n-substrate junction to the n/p+ junction. In the present embodiment, the possible Latch-up path from the LDD-n/p junction through the p-substrate/n-substrate junction to the n/LDD-p junction includes the length \textcircled{1}, the length \textcircled{2}, the length \textcircled{3}, the length \textcircled{4}, the length \textcircled{5}, the length \textcircled{6}, the length \textcircled{7}, and the length \textcircled{8} (as marked in FIG. 8) is longer than the Latch-up path in a traditional CMOS structure which combines a PMOS transistor and an NMOS transistor (not shown) without any localized isolation. Such that, from device layout point of view, the reserved edge distance between the first semiconductor device 110 and the second semiconductor device 120 in could be smaller than that of a traditional CMOS structure.

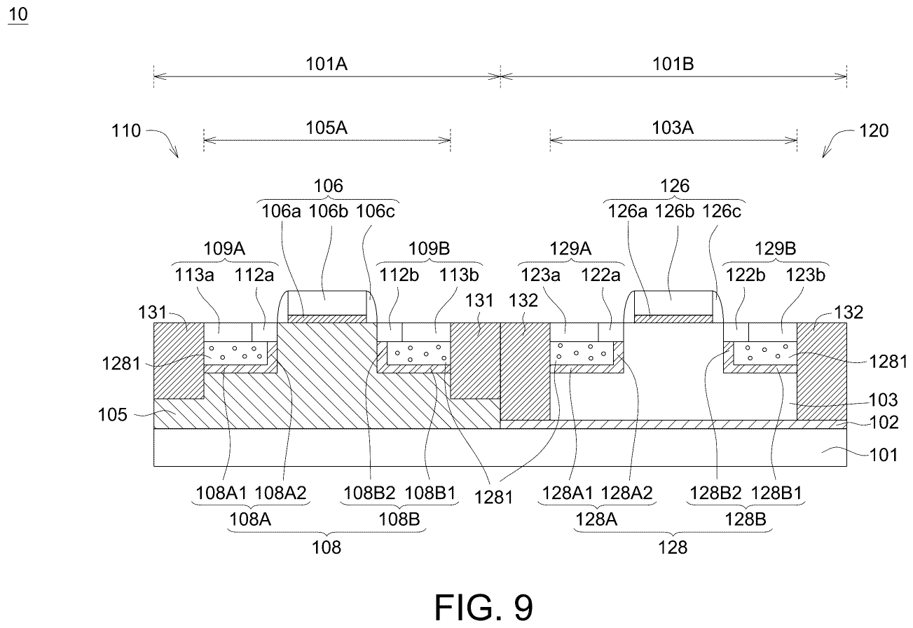

Of note that, because there is a dielectric or oxide layer 102 is disposed under the second semiconductor device 120 (N-type MOSFET), and in the event the STI regions 132 are extended into or touched with the STI regions 132 (as shown in FIG. 9) which can serve as an isolation for the Latch-up path between the first semiconductor device 110 and the second semiconductor device 120. Such that, in some embodiments of the present disclosure, the localized isolations 128A and 128B of the second semiconductor device 120 can be omitted.

In accordance with the aforementioned embodiments of the present disclosure, a semiconductor structure both having a bulk semiconductor substrate and a selective localized SOI substrate is provided based on a SOI substrate. Such that, it can effectively reduce the size of latch up design and provide devices flexibility at the same time.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
a semiconductor substrate having a first region and a second region;
an epitaxy layer disposed on and within the first region of the semiconductor substrate;
an dielectric layer, disposed on and within the second region of the semiconductor substrate;
a semiconductor layer, disposed on the dielectric layer and within the second region;
a first semiconductor device, formed on the epitaxy layer; and
a second semiconductor device, formed on the semiconductor layer.

2. The semiconductor structure according to claim 1, wherein the epitaxy layer is extended upward from a portion surface of the semiconductor substrate in the first region.

3. The semiconductor structure according to claim 1, wherein the dielectric layer is an oxide layer, the oxide layer contacts with another portion surface of the semiconductor substrate in the second region.

4. The semiconductor structure according to claim 3, wherein the semiconductor layer is a silicon layer, a top surface of the silicon layer is substantially conformal with a top surface of the epitaxy layer.

5. The semiconductor structure according to claim 1, wherein the first semiconductor device is a metal-oxide-semiconductor-field-effect-transistor (MOSFET) transistor comprises a first source/drain disposed within the epitaxy layer and a first localized isolation disposed below the first source/drain.

6. The semiconductor structure according to claim 5, wherein the first localized isolation comprises a first horizontally extended isolation portion insulating a bottom surface of the first source/drain from the semiconductor substrate, and a first vertically extended isolation portion at least partially insulating a sidewall of the first source/drain from the semiconductor substrate.

7. The semiconductor structure according to claim 1, wherein the semiconductor layer is a silicon layer, the second semiconductor device is another MOSFET comprises a second source/drain disposed within the silicon layer, the second semiconductor device further comprises a second localized isolation disposed below the second source/drain, the second localized isolation comprises a second horizontally extended isolation portion insulating a bottom surface of the second source/drain from the silicon layer, and a second vertically extended isolation portion at least partially insulating a sidewall of the second source/drain from the silicon layer.

8. The semiconductor structure according to claim 1, wherein the dielectric layer is an oxide layer, a bottom of the epitaxial layer is aligned or substantially aligned with a bottom of the oxide layer.

9. The semiconductor structure according to claim 1, wherein the semiconductor layer is a silicon layer, a vertical thickness of the epitaxial layer is larger than that of the silicon layer.

10. The semiconductor structure according to claim 1, wherein the combination of the semiconductor substrate, the dielectric layer and the semiconductor layer is a localized silicon-on-insulator (SOI) substrate.

11. A method for forming a semiconductor structure, comprising:
providing a silicon-on-insulator (SOI) substrate comprising a semiconductor substrate, an oxide layer and a silicon layer stacked in sequence;
forming a dielectric layer on the silicon layer;
removing portions of the dielectric layer, the silicon layer and the oxide layer to expose a first region of the semiconductor substrate and remaining portions of the dielectric layer, the silicon layer and the oxide layer within a second region of the semiconductor substrate;
growing an epitaxy layer on the first region;
forming a first semiconductor device on the epitaxy layer; and
forming a second semiconductor device on the remaining portion of the silicon layer.

12. The method according to claim 11, wherein growing the epitaxy layer comprises:
performing a selective epitaxial growth (SEG) process to grow epitaxial material from an exposed surface of the semiconductor substrate in the first region;
palanarizing the epitaxial material to form the epitaxy layer; and
removing the remaining portion of the dielectric layer disposed within the second region.

13. The method according to claim 12, wherein the epitaxial material is palanarized by using the remaining portion of the dielectric layer disposed on the second region as a stop layer to make the epitaxy layer having a top surface substantially conformal to a top surface of the silicon layer.

14. The method according to claim 11, wherein forming the first semiconductor device comprises:
forming a first gate structure on the top surface of the epitaxy layer;
forming a first trench below the top surface of the epitaxy layer and adjacent to the first gate structure;
forming a first localized isolation in the first trench; and
forming a first source/drain in the first trench.

15. The method according to claim 14, wherein forming the first localized isolation comprises:
performing a thermal oxidation process to form a first horizontally extended isolation portion on a bottom surface of the first trench and a first vertically extended isolation portion on sidewalls of the first trench; and
removing a portion of the first vertically extended isolation portion to expose a portion of the epitaxy layer under the first gate structure.

16. The method according to claim 15, wherein forming the first source/drain comprises:
performing a selective growth process to form a first lightly doped-drain (LDD) region from the exposed portion of the epitaxy layer under the first gate structure; and
forming a first conductive region in the first trench to electrically connected to the first LDD region.

17. The method according to claim 12, wherein forming the second semiconductor device comprises:
forming a second gate structure on the original surface of the semiconductor substrate;
forming a second trench below the original surface of the semiconductor substrate and adjacent to the second gate structure; and
forming a second source/drain in the second trench.

18. The method according to claim 17, prior to forming the second source/drain, further comprising forming a second localized isolation in the second trench.

19. The method according to claim 18, wherein forming the first localized isolation comprises:
performing a thermal oxidation process to form a second horizontally extended isolation portion on a bottom surface of the second trench and a second vertically extended isolation portion on sidewalls of the second trench; and
removing a portion of the second vertically extended isolation portion to expose a portion of the silicon layer under the second gate structure.
